(19) United States
(12) Patent Application Publication
(10) Pub. No.: US 2017/0309860 A1
(43) Pub. Date: Oct. 26, 2017

(54) DISPLAY DEVICE

(71) Applicant: KONICA MINOLTA, INC., Tokyo (JP)

(72) Inventors: Kazuyoshi OMATA, Akishima-shi, Tokyo (JP); Takatoshi TSUJIMURA, Akishima-shi, Kanagawa (JP); Tsukasa YAGI, Kobe-shi, Hyogo (JP)

(73) Assignee: KONICA MINOLTA, INC., Tokyo (JP)

(21) Appl. No.: 15/518,419

(22) PCT Filed: Oct. 20, 2015
(86) PCT No.: PCT/JP2015/079578

§ 371 Date: Apr. 11, 2017

(30) Foreign Application Priority Data
Oct. 21, 2014 (JP) 2014-214826

(51) Int. Cl. H01L 51/50; G02F 1/03

(52) U.S. Cl. CPC H01L 51/5092; H01L 51/5044; H01L 51/5036; H01L 51/5012; G02F 1/0316

(57) ABSTRACT

Provided is a display device that can reduce electric power consumption. The display device is provided with a backlight (100) and with a field-sequential display panel (200). The backlight has light-emitting units that comprise an organic electroluminescence element in which are layered a plurality of light-emitting units that emit light of different colors. The light-emitting units that can emit white light or yellow light are provided furthest to a light-emission-surface side.

### TECHNICAL FIELD

The present invention relates to a display device of a field-sequential system which is provided with an organic electroluminescence element (organic EL element) as a light source.

### BACKGROUND ART

There is proposed a display device of a field-sequential system as display devices. The field-sequential system is a system to which there is applied the fact that light beams of two or more colors are emitted by being continually switched over and the switching speed is set to a speed that exceeds a human eye's temporal resolution, and the human eye perceives the above-described two or more colors by mixing them. The field-sequential system is a color display system utilizing a color mixture on the basis of “time-division.”

In the display device of the field-sequential system, there is proposed an organic electroluminescent (EL) element instead of an LED as a directly-under type backlight or a side-edge type backlight (for example, refer to Patent Literature 1, Patent Literature 2).

The display device of the field-sequential system gives, in the moving image display, arbitrary colored light by enabling light emission of anyone color of red (R) color, green (G) color, and blue (B) color constituting back light, by emitting light through switching over (time-dividing) respective colors continually for each field, and by making the switching speed sufficiently high.

For example, each field of color is divided into a state of being spectrally separated into an R field, a G field, and a B field, and the respective fields of R, G, and B are each caused to emit light sequentially with time lags to thereby display one color field on the display panel. At this time, when the R field is displayed, the light emission of the backlight is set to red (R), when the B field is displayed, the light emission of the backlight is set to blue (B), and when the G field is displayed, the light emission of the backlight is set to green (G).

It is possible to display color moving images by continually displaying each of the three-color fields which are time-divided in the above-described way while switching over the emission colors.

Since the display device of the field-sequential system causes less loss of light due to absorption than the system in which the color filter is used, and does not use an expensive color filter, and thus the system has a great advantage because of being able to reduce the number of parts and of cost reduction.

### CITATION LIST

### Patent Literature

PTL 1: Japanese Patent Laid-Open No. 2008-66366

PTL 2: Japanese Patent Laid-Open No. 2007-172945

### SUMMARY OF INVENTION

### Technical Problem

However, in the liquid crystal display device described in Patent Literature 1, there is used a backlight in which three kinds of the organic EL elements of the organic EL element that emits light of the red (R), the organic EL element that emits light of the green (G) and the organic EL element that emits light of the blue (B) are formed on a substrate in a divided manner. In this way, when there is used the organic EL elements formed in the divided manner so as to distinguish the three colors of the red, green and blue from each other as a backlight, an area of the portion where each light is emitted is substantially ⅓ on the substrate, resulting in reduction of numerical aperture.

Furthermore, in the liquid crystal display device described in Patent Literature 2, there is used organic EL elements of a stacking structure in which light-emitting layers which emit light of the red (R), green (G) and blue (B) are laminated in the direction of light emission on a substrate, as a backlight. However, in such an organic EL element of the stacking structure, a light generated in the light-emitting layer arranged at a position furthest from the light-emission-surface (for example, the substrate) is affected by various influences such as absorption, reflection and the like through the other light-emitting layers and electrodes which are provided from the light-emitting layer to the light-emission-surface. Accordingly, the light generated in the light-emitting layer arranged at a position furthest from the light-emission-surface has lower light extraction efficiency than the light-emitting layer which arranged on the light-emission-surface side. This causes increase of the electric power consumption in the backlight of the display device of the field-sequential system, resulting in increase of the electric power consumption in the display device of the field-sequential system.

In order to solve the above-described problems, the present invention provides a display device capable of reducing the electric power consumption.

### Solution to Problem

The display device includes a backlight and a field-sequential display panel, wherein a light-emitting portion of the backlight includes an organic electroluminescence element, in the organic electroluminescence element, a plurality of light-emitting units that emit light of different colors are laminated, and a light-emitting unit that can emit white light or yellow light is provided closest to a light-emission-surface side.

### Advantageous Effects of Invention

According to the present invention, a display device capable of reducing electric power consumption can be provided.

### BRIEF DESCRIPTION OF DRAWINGS

FIG. 1 is a schematic configuration view of a display device of a first embodiment.

FIG. 2 is a schematic configuration view of the display device of a second embodiment.

FIG. 3 is an equivalent circuit chart and a timing chart of an organic EL element.

### DESCRIPTION OF EMBODIMENTS

Hereinafter, the embodiments for the present invention will be explained, but the present invention is not limited to the following examples.

Note that the explanation will be done in the following order.

1. First embodiment of the display device
2. Second embodiment of the display device
3. Timing chart

### <1. First Embodiment of the Display Device>

FIG. 1 is a schematic configuration view of a display device of field-sequential system. The display device of the field-sequential system shown in FIG. 1 is provided with a backlight 100 including a display panel 200 and an organic electroluminescence element (organic EL element).

### [Display Panel]

The display panel 200 is a crystal display panel for the field-sequential system which can be driven at a high speed by a TFT (Thin Film Transistor) system. The display panel 200 has a known configuration in the TFT system, and the display panel 200 is configured by sandwiching a liquid crystal layer 206 between two transparent substrates 202 (for example, glass substrate or transparent film substrate) which have a polarizing plate 201 on the outer surface side.

Pixel electrodes 204 and thin film transistors (TFT) 203 are formed on the lower transparent substrate 202. Furthermore, there are arranged, on the transparent substrate 202, data lines 210 and scanning lines (not shown) in a matrix manner via an insulating layer 207. In addition, there are arranged the TFT 203 and the pixel electrode 204 at the crossing point of the data line 210 and the scanning line.

Furthermore, a highly responsible liquid crystal layer 206 sandwiched by oriented films 205, above the insulating 207. In the liquid crystal layer 206, there is configured a space for sealing the liquid crystal layer 206, by a spacer 208, a seal 209 and a pair of the oriented films 205.

In order to display a full color image by the field-sequential system, a highly responsible one is required as the display panel 200, and it is preferable to use a highly responsible liquid crystal display panel utilizing a known ferroelectric liquid crystal or an anti-ferroelectric liquid crystal. Furthermore, a liquid crystal panel of OCB (Optically Compensated Bend, Optically Compensated Birefringence) type or a liquid crystal panel of MEMS (Micro Electro Mechanical Systems) type may be used. Note that the display panel 200 has a configuration of not having a color filter in order to carry out application to the display device of the field-sequential system.

### [Backlight]

Next, the backlight 100 used for the field-sequential system shown in FIG. 1 will be explained. A light-emitting portion of the backlight 100 is configured by a laminated organic EL element.

In the display device shown in FIG. 1, the organic EL element constituting the light-emitting portion of the backlight 100 has a four-layered stacking structure in which four layers of a light-emitting unit are laminated in the thickness direction (light emitting direction). In addition, the organic EL element is continuously formed all over the region of the backlight 100 in which the light-emitting portions are provided.

Furthermore, as shown in FIG. 1, the organic EL element which configures the light-emitting portion of the backlight 100 is formed on a transparent substrate 101 by laminating a first electrode 102, a first light-emitting unit 103, a first intermediate electrode 104, a second light-emitting unit 105, a second intermediate electrode 106, a third light-emitting unit 107, a third intermediate electrode 108, a fourth light-emitting unit 109 and a second electrode 110 in this order. In the organic EL element, one of the first electrode 102, the first intermediate electrode 104, the second intermediate electrode 106, the third intermediate electrode 108 and the second electrode 110 acts as a cathode and the other acts as an anode with respect to the respective sandwiched the first light-emitting unit 103, the second light-emitting unit 105, the third light-emitting unit 107 and the fourth light-emitting unit 109. Furthermore, the organic EL element is configured as a bottom-emission type in which light emitted is extracted at least from the transparent substrate 101 side.

In the present embodiment, the first light-emitting unit 103 which is provided on the side closest to the substrate is a light-emitting unit which emits white (W) light. In addition, the second light-emitting unit 105 is a light-emitting unit which emits red (R) light. The third light-emitting unit 107 is a light-emitting unit which emits green (G) light. The fourth light-emitting unit 109 is a light-emitting unit which emits blue (B) light. Note that, in the present embodiment, when the first light-emitting unit 103 is the white light, the emission color from the other second light-emitting unit 105, the third light-emitting unit 107 and the fourth light-emitting unit 109 may be either red, green and blue, and a configuration can be such that the lamination order of these light-emitting units is arbitrary. In addition, a color temperature of the white (W) is within the range of 2000 K to 12000 K.

Each electrode is connected to a drive-controlling portion in order to control the light emission of each light-emitting unit. When controlling a driving voltage applied to the electrodes which sandwich each light-emitting unit by the drive-controlling portion, driving control of each light-emitting unit of the organic EL element can be performed. The first light-emitting unit 103, the second light-emitting unit 105, the third light-emitting unit 107 and the fourth light-emitting unit 109 which emit color light of R, G, B, and W are individually driven by driving control of the light-emitting unit at the drive-controlling portion. Furthermore, light emission time, and light emission brightness for each light-emitting unit are controlled by controlling the drive.

In the backlight of the display device of the field-sequential system, the light emission is driven in the time-sharing manner by changing the emitted light of the organic EL element. In the display device, in order not to generate flicker of image due to the color change, it is necessary to change the field at about 1/60 second or less. Furthermore, in the organic EL element having the above configuration, four emission colors of R, G, B and W are obtained from the four light-emitting units. Therefore, in order to display one color per one field by driving the organic EL element of the above configuration through time division, at least it is necessary to divide one filed by four. Namely, it is necessary to drive the organic EL element through time division at least at about 1/240 second or less (about 4 milliseconds or less).

In case that a prior-art general organic EL element having three-layered stacking structure which can emit three colors of R, G, and B is used in the display device of the field-sequential system, the colors of R, G and B are emitted in this order by time-dividing the field of the color into ⅓. For example, the color field is divided, in a spectrally dispersed state, into the field of R, the field of G, and the field of B, on the display panel side. In addition, in the backlight, each field of R, G, and B is light-emitted with a time difference in order. At this time, in displaying the field of R, the emission color of the backlight is red (R), in displaying the field of B, the emission color of the backlight is blue (B), and in displaying the field of G, the emission color of the backlight is green (G).

One field of one color is displayed by continuous display of each field of the three colors which is time-divided by changing the emission color. For example, in the display device, in a case where the field of the white color (W) is to be displayed, the time-divided emitted light R, G, and B are continuously emitted in order and thus the field of R, the field of G and the field of B are continuously displayed to thereby synthesize the white color light.

However, in a case of the organic EL element having the stacking structure in which the light-emitting units are laminated, reflection, absorption and the like of the emitted light are generated in each of laminated layers. Accordingly, for example, there is a difference between an extraction efficiency of the emitted light from the light-emitting unit laminated at the side of the light emitting surface, and an extraction efficiency of the emitted light from the light-emitting unit laminated on the side opposite to the light emitting surface. Usually, the extraction efficiency of the emitted light from the light-emitting unit laminated on the side opposite to the light emitting surface becomes lower. Namely, the light-emitting efficiency of the light-emitting unit laminated on the side of the light emitting surface is high, and the light-emitting efficiency of the light-emitting unit laminated on the side opposite to the light emitting surface is low.

Furthermore, in the organic EL element having the above stacking structure, it is necessary to increase an applied voltage to each light-emitting unit and to increase the light-emitting brightness of each light-emitting layer, when the increase in the brightness is desired. Accordingly, the electric power consumption is increased. Particularly, with respect to the light-emitting unit laminated on the side opposite to the light emitting surface, it becomes necessary to apply a higher driving voltage in order to increase the brightness in accordance with the light-emitting unit laminated at the side of the light emitting surface. Therefore, in the light-emitting unit, the increase of the electric power consumption caused by the low light-emitting efficiency becomes remarkable.

In contrast, in the organic EL element of the present embodiment, the first light-emitting unit arranged closest to the light-emission-surface side has the light-emitting unit which emits W light. By provision of the light-emitting unit which emits W light, the influences of the decrease in the brightness due to absorption and the like caused by the laminated structure is less likely to be received than the case where the white light is obtained by synthesizing the light of three colors R, G and B from the three-layered light-emitting units. Accordingly, by arrangement of the light-emitting unit having the white emission color closest to the light-emission-surface side, a higher brightness can be obtained without the prevention of the emission of the white light by the other light-emitting unit. Therefore, the light-emitting efficiency of the organic EL is enhanced.

Particularly, when the light-emitting efficiency of the light-emitting unit having an emission color of W is higher than the light-emitting efficiency of the respective light-emitting units of R, G and B, the effect becomes remarkable. For example, by provision of the white light-emitting layer having high emission efficiency, in a case of trying to enhance the brightness of the organic EL element, it is sufficient to enhance the brightness of the white light-emitting layer, and it becomes unnecessary to enhance the brightness of the layers of R, G and B each having low emission efficiency. Therefore, the light-emitting efficiency of the backlight is enhanced by provision of the white light-emitting layer and thus the electric power consumption can be reduced.

Note that, in the organic EL element, it is sufficient that the light-emitting unit which emits the white light is arranged closest to the light-emission-surface side, and a configuration can be such that the light-emitting units of R, G and B are arbitrarily arranged.

With respect to the light-emitting units other than the light-emitting unit which emits the white light, the combination may not be limited to the combination of the three primary colors of R, G and B, but may be the combination of other emission colors. For example, there may be adopted a configuration in which a light-emitting unit capable of emitting any of complementary colors of yellow, cyan and magenta are provided, or a configuration in which a light-emitting unit emitting any of the three primary colors is combined with a light-emitting unit emitting the light of any of the complementary colors.

The light-emitting unit which emits the white light can be a laminated structure of, for example, the light-emitting layer which emits B and a light-emitting layer which emits yellow (YL), or may be a configuration in which a dopant for emitting the light of B and a dopant for emitting the light of YL are added. In this way, the light-emitting unit which emits the white light may have a configuration in which the light-emitting layer is composed of sole layer, or may have a configuration in which the light-emitting layer is composed of a plurality of light-emitting layers. The same also applies to the other light-emitting units of R, G and B.

Furthermore, in a case where the light-emitting unit has a configuration in which the light-emitting layer is composed of a plurality of light-emitting layers, the light-emitting layers may be directly laminated, or an intermediate connector layer which does not emit light may be provided between the respective light-emitting layers. Generally, the intermediate connector layer is also referred to as an intermediate electrode, an intermediate conductive layer, an electric charge-generating layer, an electron pull out layer, a connecting layer, an intermediate insulating layer, and can be obtained by the use of well-known material configurations as long as the intermediate connector layer has functions of transporting an electron to an adjacent layer on the anode side and transporting a positive hole to an adjacent layer on the cathode side. For example, a similar configuration to that of the intermediate electrode described below can be used.

### [Organic EL Element]

Next, each configuration of the organic EL element constituting the light-emitting portion of the backlight will be explained. In the organic EL element, the first electrode 102, the first intermediate electrode 104, the second intermediate electrode 106, and the third intermediate electrode 108 are constituted as a translucent electrode. In addition, only the first light-emitting unit 103, the second light-emitting unit 105 and the third light-emitting unit 107 which are sandwiched by the first electrode 102, the first intermediate electrode 104, the second intermediate electrode 106, the third intermediate electrode 108 and the second electrode 110 are the light-emitting regions in the organic EL element. Hereinafter, these configurations will be explained in detail.

### [Substrate]

The substrate 101 of the organic EL element can include, for example, a glass, plastics, and the like, but is not limited thereto. A preferable substrate 101 can include a glass, a quartz, and a transparent resin film.

Examples of the resin film include: polyesters such as polyethylene terephthalate (PET) and polyethylene naphthalate (PEN); polyethylene; polypropylene; cellulose esters or derivative thereof such as cellophane, cellulose diacetate, cellulose triacetate (TAC), cellulose acetate butylate, cellulose acetate propionate (CAP), cellulose acetate phthalate and cellulose nitrate; polyvinylidene chloride; polyvinyl alcohol; polyethylene vinyl alcohol; syndiotactic polystyrene; polycarbonate; norbornen resin; polymethylpenten; polyether ketone; polyimide; polyether sulphone (PES); polyphenylene sulfide; polysluphones; polyether imide; polyether ketone imide; polyamide; fluoro resin; Nylon; polymethyl methacrylate; acryl or polyallylates; cycloolefins-based resins such as Alton (commercial name of JSR) or APEL (commercial name of Mitsui Chemicals).

### [First Electrode]

The first electrode 102 is the transparent electrode in the organic EL element and is an electrically conductive layer constituted by the use of silver or an alloy containing silver as a principal component. Here, the principal component means a component having the highest composition ratio among the components constituting the first electrode 102.

Examples of the alloys consituting the first electrode 102 and containing silver (Ag) as a principal component include silver magnesium (AgMg), silver copper (AgCu), silver palladium (AgPd), silver palladium copper (AgPdCu), silver indium (AgIn), and the like.

The first electrode 102 may have a configuration of laminated layers in which the layers of silver or the alloy containing silver as a principal component are laminated by being divided into a plurality of layers, as necessary.

Furthermore, the layer thickness of the first electrode 102 is preferably within the range of 2 to 15 nm, more preferably within the range of 3 to 12 nm, and particularly preferably within the range of 4 to 9 nm. When the layer thickness is less than 15 nm, the absorbing components or the reflective components of the layer are small, and thus the light transmittance of the first electrode 102 becomes large. In addition, when the layer thickness is more than 2 nm, it is possible to sufficiently ensure the conductivity of the layer.

The method for depositing the first electrode 102 includes a method using a wet process such as an applying method, an inkjet method, a coating method or a dipping method, or a method using a dry process such as a vapor deposition method (resistance heating, an EB method, and the like), a sputtering method, or a CVD method. Among them, the vapor deposition method is preferably employed.

### [Underlayer]

In addition, the first electrode 102 constituted by the use of silver or the alloy containing silver as a principal component is preferably formed on the following underlayer. The underlayer is a layer provided on the transparent substrate 101 side of the first electrode 102.

The material constituting the underlayer is not particularly limited, and includes: a compound or the like which can suppress the aggregation of silver and which contains nitrogen atom or sulfur atom, in the deposition of, for example, the first electrode 102 composed of silver or the alloy containing silver as a principal component; a layer containing metals such as Pd, Al, Ti, Pt and Mo which serve as a growth nucleus in the deposition of silver; and a layer containing zinc oxide.

In a case where the underlayer is composed of a material having a low refractive index (refractive index of less than 1.7), the upper limit of the thickness is required to be less than 50 nm, preferably less than 30 nm, further preferably less than 10 nm, and particularly preferably less than 5 nm. When the thickness is less than 50 nm, the optical loss is minimized. On the other hand, the lower limit of the thickness is required to be 0.05 nm or more, preferably 0.1 nm or more, and particularly preferably 0.3 nm or more. When the thickness is 0.05 nm or more, it is possible to achieve uniform deposition of the underlayer and to uniformly achieve the effect (suppression of aggregation of silver).

In a case where the underlayer is composed of a material having a high refractive index (refractive index of 1.7 or more), the upper limit is not particularly limited, and the lower limit of the thickness is the same as the case of the above material having a low refractive index.

However, it is sufficient that the underlayer is formed having a necessary thickness that gives uniform deposition, simply as a function of the underlayer.

In a case where the underlayer is a layer including a metal serving as a growth nucleus of silver, the thickness of the layer is a thickness that does not inhibit the light transmittance of the organic EL element, and may be preferably, for example, 5 nm or less. In contrast, the underlayer is required to have a thickness that can ensure the film uniformity of the first electrode 102. The underlayer having a thickness like this may be a layer in which each metal atom forms at least one atomic layer. Furthermore, the underlayer is preferably a continuous layer. Note that, in the underlayer, even if defects exist in the continuous phase of the layer including the metal serving as a growth nucleus of silver, it is possible to ensure a film uniformity of the first electrode 102 as long as the defect is smaller than the Ag atom constituting the first electrode 102.

The nitrogen atom-containing compound constituting the underlayer is not particularly limited as long as the compound contains a nitrogen atom within the molecule, and is preferably a compound having a heterocyclic ring containing a nitrogen atom as the hetero atom. Examples of the heterocyclic rings containing a nitrogen atom as the hetero atom include aziridine, azirine, azetidine, azete, azolidine, azoles, ajinan, pyridine, azepane, azepine, imidazole, pyrazole, oxazole, thiazole, imidazoline, pyrazine, morpholine, thiazine, indole, isoindole, benzimidazole, purine, quinoline, isoquinoline, quinoxaline, cinnoline, pteridine, acridine, carbazole, benzo-C-cinnoline, porphyrins, chlorins, choline, and the like.

Examples of the methods for deposition of the underlayer include: a method using a wet process such as an application method, an inkjet method, a coating method, or a dipping method; a method using a dry process such as a vapor deposition method (resistance heating, EB method, and the like), a sputtering method, an ion-plating method, a plasma CVD method or a heat CVD method; and the like. Among them, the underlayer is preferably fromed by an electron beam vapor deposition method or a sputtering method, from the viewpoint of deposition property. In the case of the electron beam vapor deposition method, it is preferable to use an assist such as IAD (ion assist), or the like in order to enhance the film density.

Furthermore, the layer including zinc oxide (zinc oxide-containing layer) constituting the underlayer contains zinc oxide (ZnO) as a principal component. Here, the principal component in the zinc oxide-containing layer is a component having the highest percentage among the components constituting the layer, and the percentage is preferably 50% by atom or more. It is possible to make uniform the alinement of the silver atoms contained in the first electrode 102 and to achieve both of light transmittance and resistance property, by the use of the zinc oxide-containing layer as the underlayer of the first electrode 102.

In the zinc oxide-containing layer may contain materials other than zinc oxide. A dielectric material or an oxide semiconductor material as the materials other than zinc oxide contained in the zinc oxide-containing layer may be an insulation material or a conductive material. Examples of the dielectric material or the oxide semiconductor material contained in the zinc oxide-containing layer include TiO₂, ITO (indium-tin oxide), ZnS, Nb₂O₅, ZrO₂, CeO₂, Ta₂O₅, Ti₃O₅, Ti₄O₇, Ti₂O₃, TiO, SnO₂, La₂Ti₂O₇, IZO (indium oxide-zinc oxide), AZO (Al-doped ZnO), GZO (Ga-doped ZnO), ATO (Sb-doped SnO), ICO (indium cerium oxide), Ga₂O₃, and the like. The zinc oxide-containing layer may contain the dielectric material or the oxide semiconductor material of one kind or two or more kinds. The dielectric material or the oxide semiconductor material is particularly preferably ZnS, TiO₂, GZO or ITO.

Note that the zinc oxide-containing layer may contain MgF₂, SiO₂, and the like other than the above dielectric material or the oxide semiconductor material. For example, the zinc oxide-containing layer contains SiO₂, the layer easily becomes amorphous, and flexibility of the organic EL element is easily enhanced.

The zinc oxide-containing layer preferably contains zinc oxide as a principal component from the viewpoint of suppressing the aggregation of silver at the time of the deposition of the first electrode 102 and of obtaining the first electrode 102 having a small thickness but a uniform thickness. The amount of zinc atom contained in the zinc oxide-containing layer is preferably 0.1 to 50 at %, more preferably 0.5 to 50 at % relative to the whole atoms constituting the zinc oxide-containing layer.

On the other hand, when the amount of the zinc atom is excessive, it becomes difficult to uniformly deposit the zinc oxide-containing layer, and thus there is a case where the transparency is lowered. The types and contents of the atoms contained in the first electrode 102 are specified by, for example, an XPS method, and the like.

Generally, the thickness of the zinc oxide-containing layer is preferably 3 to 35 nm, more preferably 5 to 25 nm. When the thickness of the zinc oxide-containing layer is 3 nm or more, a deposition property of the first electrode 102 is sufficiently enhanced. On the other hand, when the thickness of the zinc oxide-containing layer is 35 nm or less, there is a small influence of the organic EL element on the optical properties, the light transmittance of the organic EL element is difficult to be lowered. The thickness of the zinc oxide-containing layer is measured by an ellipsometer, or the like.

Although the first electrode 102 has a feature of having, by deposition on the underlayer, sufficient conductivity even without a high temperature annealing treatment after the deposition of the first electrode 102, the first electrode may be subjected to the high temperature annealing treatment after the deposition as necessary.

When the first electrode 102 having Ag as a principal component is formed on the substrate, the Ag atoms adhering to the substrate form a mass (core) having a certain size while being diffused on the surface. Then, initial growth of a thin film proceeds along a periphery of the mass (core). Accordingly, the film of the initial stage is not electrically conductive since there is a space between the masses. When the masses further grow from the state and each of the thicknesses of the masses becomes about 15 μm, parts of the masses are connected to each other and become barely electrically conductive. However, the surface of the film is not yet flat, plasmon absorption is easily generated.

In contrast, when there is previously formed, as the underlayer, a layer containing a metal serving as a growth nucleus in the deposition of silver, such as Pd, Al, Ti, Pt or Mo, the metal material such as Ag constituting the first electrode 102 becomes difficult to move on the underlayer. Furthermore, the metal atom such as Pd can make the space between growth nuclei narrower than the space between the masses formed through the surface diffusion of the Ag atoms. Therefore, when the Ag layer grows from the Pd growth nucleus, the obtained film becomes easily flat even if the thickness is small.

Moreover, it is possible to have a configuration in which, for example, the first electrode 102 of silver or the alloy containing silver as a principal component is provided on the underlayer constituted by the use of the compound containing a nitrogen atom. Accordingly, in depositing the first electrode 102 on the underlayer, the silver atom constituting the first electrode 102 interacts with the compound containing a nitrogen atom constituting the underlayer, the diffusion distance of the silver atom on the surface of the underlayer becomes short, and thus the aggregation of the silver is suppressed.

In addition, the zinc atom contained in the zinc oxide-containing layer has an affinity with the silver of the first electrode 102. Therefore, at the time of the deposition of the first electrode 102, the silver constituting the first electrode 102 becomes hard to be aggregated on the zinc oxide-containing layer, and thus it is possible to form the thin and uniform first electrode 102. Furthermore, since the zinc atom has an affinity with the silver contained in the first electrode 102, it is possible to suppress the aggregation of the silver due to moisture under a high humidity circumstance, and corrosion of the silver.

Namely, in the deposition of the silver in which the silver particle is easily isolated in an island shape by the nucleus-growth type (Volmer-Weber: VW-type), the aggregation of the silver to be deposited is suppressed by the use of the above underlayer. Accordingly, in the deposition of the first electrode 102 composed of silver or the alloy containing silver as a principal component, the thin film grows according to the mono-layer growth type (Frank-van der Merwe: FM type). Therefore, as described above, the first electrode 102 composed of silver or the alloy containing silver as a principal component assures electric conductivity at a smaller thickness, and it becomes possible to achieve both of the enhancement of the conductivity and the enhancement of the light transmittance, in the first electrode 102.

### [Intermediate Electrode]

In the organic EL element, there are provided the intermediate electrodes of the first intermediate electrode 104, the second intermediate electrode 106 and the third intermediate electrode 108, between the first light-emitting unit 103, the second light-emitting unit 105, the third light-emitting unit 107 and the fourth light-emitting unit 109. These intermediate electrodes preferably have a small absorption component and reflection component of the layer, and have a large light transmittance.

A similar configuration to that of, for example, the above first electrode 102 can be applied to the intermediate electrode. A film of silver or an alloy containing silver can be used as a principal component, having a thickness of, for example, 2 to 15 nm. When a film of silver or an alloy containing silver as a principal component is formed as the intermediate electrode, the intermediate electrode may be formed on the above underlayer. Alternatively, the intermediate electrode may be directly formed on the organic material layer such as an electron transport layer constituting the light-emitting unit.

In addition, a film of aluminum having a thickness of, for example, 5 nm to 20 nm can be used as the intermediate electrode. Furthermore, it is possible to adopt a configuration in which the aluminum and the above silver are laminated, and a configuration in which the other conductive material is laminated.

Moreover, there can be used, as the intermediate electrode, an electrically conductive inorganic compound layer such as ITO (indium tin oxide), IZO (indium zinc oxide), ZnO₂, TiN, ZrN, HfN, TiOₓ, VOₓ, CuI, InN, GaN, CuAlO₂, CuGaO₂, SrCu₂O₂, LaB₆, or RuO₂, a two-layered film such as Au/Bi₂O₃, a multi-layered film such as SnO₂/Ag/SnO₂, ZnO/Ag/ZnO, Bi₂O₃/Au/Bi₂O₃, TiO₂/TiN/TiO₂, or TiO₂/ZrN/TiO₂, a fullerene such as C₆₀, and an electrically conductive organic layer such as oligothiophene, metal phthalocyanine, metal-free phthalocyanine, metal porphyrin, or metal-free porphyrin, and the like.

### [Second Electrode]

The second electrode 110 is an electrode film having, for example, a function that supplies electrons to the fourth light-emitting unit 109 and serving as a counter electrode with respect to the third intermediate electrode 108 being a transparent electrode. There is used, as the second electrode 110, an electrode composed of an electrode material having a low work function (4 eV or less) such as a metal (referred to as an electron-injecting metal), an alloy, an electrically conductive compound, or a mixture thereof.

The sheet resistance as the second electrode 110 is preferably several Ω/square or less, and the thickness thereof is selected usually within the range of 10 nm to 5 μm, preferably in the range of 50 nm to 200 nm.

Specific examples of such electrode materials as described above include sodium, a sodium-potassium alloy, magnesium, lithium, a magnesium/copper mixture, a magnesium/silver mixture, a magnesium/aluminum mixture, a magnesium/indium mixture, an aluminum/aluminum oxide (Al₂O₃) mixture, indium, a lithium/aluminum mixture, a rare earth metal, and the like.

Among them, from the viewpoint of electron injection property and durability against oxidation, preferred examples are a mixture of the electron-injecting metal and a secondary metal that is a metal having a work function higher than that of the electron-injecting metal and being more stable, such as a magnesium/silver mixture, a magnesium/aluminum mixture, a magnesium/indium mixture, an aluminum/aluminum oxide (Al₂O₃) mixture, a lithium/aluminum mixture, aluminum, and the like.

The second electrode 110 can be fabricated by formation of each of thin films of the electrode materials by a method such as vapor deposition or sputtering.

### [Light-Emitting Unit]

The first light-emitting unit 103, the second light-emitting unit 105, the third light-emitting unit 107 and the fourth light-emitting unit 109 contains at least a luminescent organic material, and have the light-emitting layer that emits each light of white, red, green or blue, and further may have other layer between the light-emitting layer and the electrode.

Representative element configurations of the first light-emitting unit 103, the second light-emitting unit 105, the third light-emitting unit 107 and the fourth light-emitting unit 109 are as follows, but the present invention is not limited thereto.

(1) Anode/light-emitting layer/cathode
(2) Anode/light-emitting layer/electron transport layer/cathode
(3) Anode/positive hole transport layer/light-emitting layer/cathode
(4) Anode/positive hole transport layer/light-emitting layer/electron transport layer/cathode
(5) Anode/positive hole transport layer/light-emitting layer/electron transport layer/electron injection layer/cathode
(6) Anode/positive hole injection layer/positive hole transport layer/light-emitting layer/electron transport layer/cathode
(7) Anode/positive hole injection layer/positive hole transport layer/(electron-blocking layer)/light-emitting layer/(positive hole-blocking layer)/electron transport layer/electron injection layer/cathode

Among them, the configuration (7) is preferably used, but the present invention is not limited thereto.

In the above representative element configurations, layers other than the anode and cathode are the light-emitting units.

### (Light-Emitting Unit)

In the above configuration, the light-emitting layer is composed of a mono-layer or multi-layer. When the light emitting layer is plural, a non-light-emitting intermediate layer may be provided between the respective light-emitting layers.

As necessary, a positive hole-blocking layer (positive hole barrier layer), an electron injection layer (cathode buffer layer) or the like may be provided between the light-emitting layer and the cathode, and an electron-blocking layer (electron barrier layer), a positive hole injection layer (anode buffer layer) or the like may be provided between the light-emitting layer and the anode.

The electron transport layer is a layer having a function of transporting an electron. The electron transport layer also includes the electron injection layer, and the positive hole-blocking layer, in a broad sense. Furthermore, the electron transport layer unit may be composed of plural layers.

The positive hole transport layer is a layer having a function of transporting a positive hole. The positive hole transport layer also includes the positive hole injection layer, and the electron-blocking layer, in a broad sense. Furthermore, the positive hole transport layer may be composed of plural layers.

### [Light-Emitting Layer]

In the light-emitting layer, it is preferable to contain a phosphorescence-emitting compound as the light-emitting material. Furthermore, the light-emitting layer may be used by mixture of a plurality of light-emitting materials, or by mixture of a phosphorescence-emitting compound and a fluorescence-emitting material (fluorescent dopant, fluorescent compound) in the same light-emitting layer. It is preferable that the light-emitting layer contains a host compound (emitting host, and the like) and a light-emitting material (light-emitting dopant) as its configuration, and emits light by the use of the light-emitting material. The light-emitting layer can be formed through deposition of the light-emitting material and the host compound, by a well-known thin film forming method such as a vacuum vapor deposition method, a spin coating method, a casting method, an LB method or an inkjet method.

The configuration of the light-emitting layer is not particularly limited as long as the light-emitting material contained therein satisfies a light emission requirement. The light-emitting layer is a layer that emits light by recombination of electrons injected from an electrode or an electron transport layer, and positive holes from the positive hole transport layer, and a portion that emits light may be either the inside of the light-emitting layer or an interface between the light-emitting layer and its adjacent layer. Furthermore, there may be a plurality of light-emitting layers having the same emission spectrum or emission maximum wavelength. In such a case, a non-luminescent auxiliary layer may be present between the light-emitting layers.

The total thickness of the light-emitting layers is preferably within a range of 1 to 100 nm and, more preferably within a range of 1 to 30 nm from the viewpoint of being capable of obtaining a lower driving voltage. In a case of the light-emitting layer having a configuration obtained by lamination of a plurality of layers, it is preferable to adjust the thickness of individual light-emitting layer to be within a range of 1 to 50 nm and it is more preferable to adjust the thickness thereof to be within a range of 1 to 20 nm. Note that the total thickness of the light-emitting layers has a thickness including the thickness of the intermediate layers, in a case where non-luminescent intermediate layers are present between the light-emitting layers.

### (1) Host Compound

The preferable host compound contained in the light-emitting layer is preferably a compound having, in phosphorescence emission at room temperature (25° C.), a phosphorescence quantum yield of less than 0.1. More preferable phosphorescence quantum yield is less than 0.01. Furthermore, a compound having a volume ratio of 50% or more in the light-emitting layer is preferable, among the compounds contained in the layer.

A well-known host compound may be used alone or in combination of a plurality of kinds, as the host compound. It is possible to adjust transfer of charges and increase an efficiency of the organic EL element, by the use of a plurality of the host compounds. Furthermore, it becomes possible to mix different colors of light to be emitted, by the use of a plurality of light-emitting materials mentioned below, and thus an arbitrary emission color can be obtained.

### (2) Light-Emitting Material

A phosphorescence-emitting compound (phosphorescent compound, phosphorescence-emitting material) and fluorescence-emitting compound (fluorescent compound, fluorescence-emitting material) can be used as the light-emitting material.

### (Phosphorescence-Emitting Compound)

The phosphorescence-emitting compound is defined as a compound in which light emission from an excited triplet state is observed, and, specifically, a compound that emits phosphorescence at room temperature (25° C.), and a phosphorescence quantum yield at 25° C. is 0.01 or more, and preferable phosphorescence quantum yield is 0.1 or more.

The above-described phosphorescence quantum yield can be measured by a method described on page 398 of Bunko II of Dai 4 Han Jikken Kagaku Koza 7 (1992, published by Maruzen Co., Ltd.). The phosphorescence quantum yield in a solution can be measured by the use of various solvents, and when the phosphorescence-emitting compound is used, it is sufficient to achieve the above-described phosphorescence quantum yield (0.01 or more) in any of appropriate solvents.

The phosphorescence-emitting compound can be used by suitable selection from the well-known phosphorescence-emitting compounds used for light-emitting layers of organic EL elements. The phosphorescence-emitting compound is preferably a complex-based compound containing a metal of the groups 8 to 10 in the element periodic table, and more preferable is an iridium compound, an osmium compound, a platinum compound (a platinum complex compound) or a rare earth complex, and most preferable is an iridium compound.

At least one light-emitting layer may contain two or more types of phosphorescence-emitting materials, and a ratio of concentration of the phosphorescence-emitting compound in the light-emitting layer may vary in the direction of thickness of the light-emitting layer. An amount of the phosphorescence-emitting compound is preferably 0.1% or more by volume and less than 30% by volume relative to the total volume of the light-emitting layer.

### (Fluorescence-Emitting Compound)

Examples of the fluorescence-emitting compound include a coumarin-based dye, a pyran-based dye, a cyanine-based dye, a croconium-based dye, a squarylium-based dye, an oxobenzanthracene-based dye, a fluorescein-based dye, a rhodamine-based dye, a pyrylium-based dye, a perylene-based dye, a stilbene-based dye, a polythiophene-based dye, a rare earth complex-based phosphor, or the like.

### [Injection Layer: Positive Hole Injection Layer, Electron Injection Layer]

The injection layer is a layer provided between an electrode and the light-emitting layer in order to decrease a driving voltage and to enhance an emission luminance, and is detailed in Part 2, Chapter 2 “Denkyoku Zairyo” (pp. 123-166) of “Yuki E L Soshi To Sono Kogyoka Saizensen (Nov. 30, 1998, published by N. T. S Co., Ltd.)”, and examples thereof include a positive hole injection layer and an electron injection layer.

The injection layer can be provided as necessary. The positive hole injection layer may be present between an anode (positive electrode) and the light-emitting layer or the positive hole transport layer, and the electron injection layer may be present between a cathode (negative electrode) and the light-emitting layer or the electron transport layer.

It is desirable that the electron injection layer is a very thin film, and the thickness thereof is within a range of 1 nm to 10 μm although the thickness depends on the material thereof.

### [Positive Hole Transport Layer]

The positive hole transport layer is made of a positive hole transport material having a function of transporting positive holes, and the positive hole injection layer and an electron-blocking layer are included in the positive hole transport layer, in abroad sense. The positive hole transport layer can be provided as a sole layer or as a plurality of layers. Furthermore, the positive hole transport layer may have a single layer structure constituted of one or two or more of the materials. The thickness of the positive hole transport layer is not particularly limited, but it is generally within a range about from 5 nm to 5 μm, preferably within a range from 5 nm to 200 nm.

The positive hole transport material is a material having a capability to inject or transport positive holes or an electron barrier property and may be either organic or inorganic. Furthermore, it is possible to enhance a p property by doping the material of the positive hole transport layer, with impurities. Preferably, the positive hole transport layer having a high p property makes it possible to produce an element which consumes lower electric power.

The positive hole transport layer can be formed by making the above-described positive hole transport material a thin film by a well-known method such as the vacuum vapor deposition method, the spin coating method, the casting method, the printing method including the inkjet method, or the LB method.

### [Electron Transport Layer]

The electron transport layer is made of a material having a function of transporting electrons, and the electron injection layer and a positive hole-blocking layer (not shown) are included in the electron transport layer, in a broad sense. The electron transport layer can be provided as a single layer structure or a laminated layer structure of a plurality of layers. Furthermore, the electron transport layer may have a single layer structure including one or more of materials. In addition, the thickness of the electron transport layer is not particularly limited, but the thickness is generally within a range of approximately 5 nm to 5 μm, preferably within a range of 5 nm to 200 nm.

In the electron transport layer having a single layer structure and the electron transport layer having a laminated layer structure, the electron transport material (also being the positive hole-blocking layer) constituting a layer portion adjacent to the light-emitting layer may have a function of transferring electrons injected from the cathode to the light-emitting layer. An arbitrary compound can be selected for use from among previously well-known compounds, as such a material.

Furthermore, the above nitrogen-containing compound constituting the underlayer may be used as the material fourthe electron transport layer (electron transporting compound). This also applies to the electron transport layer serving also as the electron injection layer, and a similar material to the material constituting the underlayer described above may be used.

The electron transport layer can be formed by making the above-described electron transport material a thin film by the use of a well-known method such as the vacuum vapor deposition method, the spin coating method, the casting method, the printing method including the inkjet method or the LB method.

### [Blocking Layer: Positive Hole-Blocking Layer, Electron-Blocking Layer]

The blocking layer is provided as necessary in addition to a basic constituent layer of a thin organic compound film as described above. Examples thereof include a positive hole-blocking layer described in documents such as Japanese Patent Laid-Open Nos. 11-204258 and 11-204359, and p. 237 of “Yuki E L Soshi To Sono Kogyoka Saizensen (Organic EL Element and Front of Industrialization thereof) (Nov. 30, 1998, published by N. T. S Co., Ltd.)”, and the like.

The positive hole-blocking layer has a function of the electron transport layer, in a broad sense. The positive hole-blocking layer is made of a positive hole-blocking material having remarkably a small capability to transport positive holes while having a function of transporting electrons, and can enhance a recombination probability of electrons and positive holes by blocking positive holes while transporting electrons. In addition, the configuration of an electron transport layer can be used for the positive hole-blocking layer, as necessary. Preferably, the positive hole-blocking layer is provided adjacent to the light-emitting layer.

On the other hand, the electron-blocking layer has a function of the positive hole transport layer, in abroad sense. The electron-blocking layer is made of a material having remarkably a small capability to transport electrons while having a function of transporting positive holes, and can enhance a recombination probability of electrons and positive holes by blocking electrons while transporting positive holes. Furthermore, the configuration of a positive hole transport layer can be used for the electron-blocking layer, as necessary. The thickness of the positive hole-blocking layer is preferably 3 to 100 nm, more preferably 5 to 30 nm.

### <2. Second Embodiment of Display Device>

Next, the second embodiment of the display device of the field-sequential system will be explained. The second embodiment is different from the first embodiment only in the configuration of the organic EL element of the backlight. Accordingly, in the following explanation, only the configuration of the organic EL element will be explained, but the configuration of the display panel, and the like, and the overlapped explanation in each configuration will be omitted.

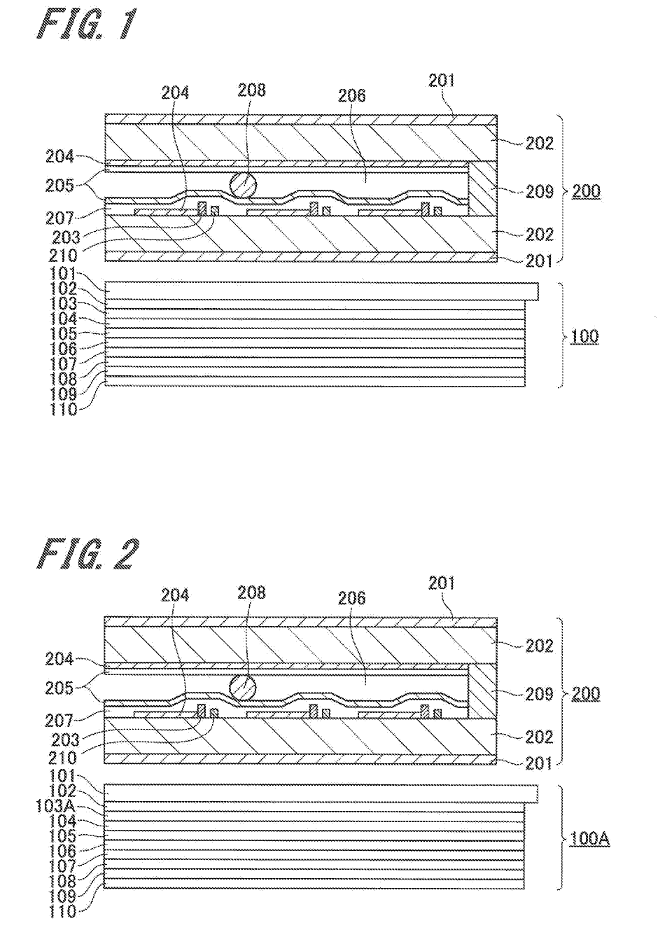

FIG. 2 is a schematic configuration view of the display device of the field-sequential system of the second embodiment. The display device of the field-sequential system shown in FIG. 2 includes a display panel 200 and a backlight 100A composed of an organic electroluminescence element (organic EL element).

In the display device of the field-sequential system shown in FIG. 2, the organic EL elements constituting the light-emitting portion of the backlight 100A has a so-called four-layered stacking structure in which the light-emitting units of four layers are laminated in the thickness direction (in the light-emitting direction). In addition, a first light-emitting unit 103A is a light-emitting unit which emits a yellow light (YL). Note that the configurations of the first electrode 102, the first intermediate electrode 104, the second light-emitting unit 105, the second intermediate electrode 106, the third light-emitting unit 107, the third intermediate electrode 108, the fourth light-emitting unit 109 and the second electrode 110 are similar to those in the above-described first embodiment.

When the first light-emitting unit 103A arranged closest to the light-emitting-surface side is provided with the YL light-emitting unit, there can be obtained the same effects of the first embodiment in which the above-described first light-emitting unit is provided with the W light-emitting unit. By arrangement of the first light-emitting unit 103A, the influences of the brightness loss such as absorption and the like due to the laminated structure is less likely to be received than the case where YL is obtained by the synthesis from R and G. Accordingly, the YL emission is not inhibited by the other light-emitting units, and a higher brightness can be obtained.

Particularly, by provision of the YL light-emitting unit having a light transmittance higher than those of R, G and B, the YL light emission is not inhibited by the other light-emitting units, and a higher brightness can be obtained. Accordingly, the light emission efficiency of the organic EL element can be enhanced. Therefore, the light emission efficiency of the backlight is enhanced by provision of the first light-emitting unit 103A having the YL emitting light, and the electric power consumption can be lowered.

Note that, in the organic EL element, it is sufficient that the light-emitting unit which emits the YL light is arranged closest to the light-emission-surface side, and arrangement of the respective light-emitting units of R, G and B may be arbitrary. Furthermore, a similar configuration to each of the configurations of the respective light-emitting units in the first embodiment can be applied as the detailed configurations of the first light-emitting unit 103A, the second light-emitting unit 105, the third light-emitting unit 107, and the fourth light-emitting unit 109 for the R, G, B, and YL.

### <3. Timing Chart>

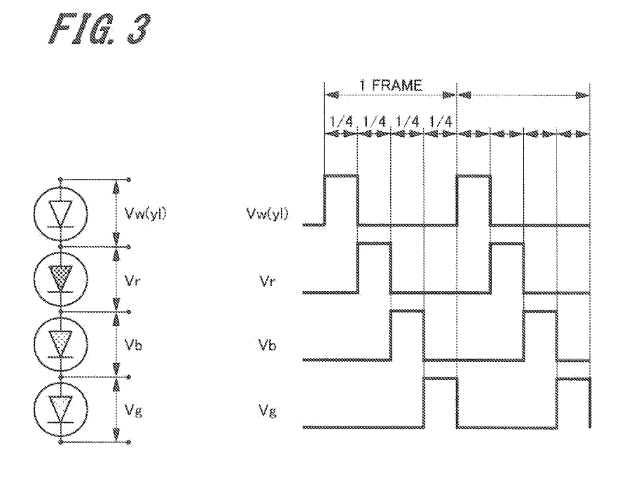

Next, FIG. 3 shows an equivalent circuit chart and a timing chart of the organic EL element.

Pairs of electrodes (the first electrode 102, the first intermediate electrode 104, the second intermediate electrode 106, the third intermediate electrode 108 and the second electrode 110 shown in FIG. 1 or FIG. 2) which sandwich the first light-emitting unit 103, the second light-emitting unit 105, the third light-emitting unit 107 and the fourth light-emitting unit 109, respectively are connected in parallel. Here, as an example, there will be explained a case where the first light-emitting unit 103 emits the white (W) or the yellow (YL) light, the second light-emitting unit 105 emits the red (R) light, the third light-emitting unit 107 emits the blue (B) light, and the fourth light-emitting unit 109 emits the green (G) light will be explained.

The timing chart shown in FIG. 3 shows the driving timing of the display panel and the light-emitting timing of each light-emitting unit of the organic EL element of the backlight. With respect to the organic EL region (pixel), when each field of R, G, B and W (or YL) is sequentially driven to thereby form one frame, the timing chart of the driving pulses of Vr, Vg, Vb, and Vw (or Vyl) is shown.

The light-emitting unit sequentially time-divides each color of R, G, B and W (or YL), for example, divides one frame into four equal portions (¼ frame) to emit light of each color. Then, the display panel shields the time-divided light by synchronization for each of three primary colors, and the field image of each color which has been time-divided (R field, G field, B field) is sequentially formed.

Then, one frame image can be formed by temporal color mixture of the field image of each color time-divided.

Although, in the above-described timing chart, explanation has been made in a case where the ratio of the light emission period of each light-emitting unit of R, G, B and W (YL) is the same, the ratio of the light emission period of each light-emitting unit can also be arbitrarily changed.

Particularly, it is possible to prolong the life of the backlight by regulating each of the light emission period of R, G, B and W (YL) corresponding to the life of each light-emitting unit. At that time, it is preferable that a light emission period of a light-emitting unit having a relatively large deterioration (short life) with passage of time is made longer than the other light-emitting units. For example, it is preferable that the ratio of the light emission period of the light-emitting unit having the shortest life is made longest. Accordingly, it is possible to suppress the lowering of brightness of the backlight and change of chromaticity due to the deterioration with passage of time, and thus the reliability of the display device is enhanced.

Method for producing the image signal (gradation data) of W is as follows.

When the smallest image signal among image signals of R, G, B is assumed to be M gradation, gradation data of image signal of W is α×M (in which a is a multiplier of 0 or more and 1 or less). When the constant α is 1, the electric power consumption becomes smallest, but usually the value is approximately 0.8 in view of appearance, and the like.

In a similar way to the case of YL, similarly, when the smallest image signal among image signals of R, G is assumed to be N gradation, gradation data of image signal of YL is β×N (in which β is a multiplier of 0 or more and 1 or less). When the constant β is 1, the electric power consumption becomes smallest, but usually the value is approximately 0.8 in view of appearance, and the like.

### [Effects]

In the above-described display devices of the field-sequential system of the first embodiment and the second embodiment, the first light-emitting unit arranged closest to the light-emission-surface side has the light-emitting unit which emits the W or YL light. By provision of the light-emitting unit thatch emits light of the W or YL, the influences of the absorption or the like caused by the laminated structure is less likely to be received than a case where only three emission colors of R, G and B are used. Accordingly, it is possible to obtain a higher brightness. Therefore, the light-emitting efficiency of the organic EL element is enhanced, and the electric power consumption of the backlight can be lowered. In addition, lowered electric power consumption of the display device of the field-sequential system becomes possible.

Note that the present invention is not limited to the configurations explained in the above embodiments, and other various modifications and changes are possible within the scope not departing from the other configurations of the present invention.

### REFERENCE SIGNS LIST

100, 100A Backlight
101 Transparent substrate
102 First electrode
103, 103A First light-emitting unit
104 First intermediate electrode
105 Second light-emitting unit
106 Second intermediate electrode
107 Third light-emitting unit
108 Third intermediate electrode
109 Fourth light-emitting unit
110 Second electrode
200 Display panel
201 Polarizing plate
202 Transparent substrate
203 Thin film transistor
204 Pixel electrode
205 Oriented film
206 Liquid crystal layer
207 Insulating layer
208 Spacer
209 Seal
210 Data line

1. A display device comprising a backlight and a field-sequential display panel, wherein
a light-emitting portion of the backlight includes an organic electroluminescence element,
in the organic electroluminescence element, a plurality of light-emitting units that emit light of different colors are laminated, and
a light-emitting unit that can emit white light or yellow light is provided closest to a light-emission-surface side.

2. The display device according to claim 1, wherein a light-emitting unit which emits a red light, a light-emitting unit which emits a green light, and a light-emitting unit which emits a blue light are provided.

3. The display device according to claim 1, wherein a light emitting efficiency of the light-emitting unit that can emit white light or yellow light is higher than efficiencies of the light-emitting unit that emits red light, the light-emitting unit that emits green light, and the light-emitting unit that emits blue light.

4. The display device according to claim 1, wherein at least one electrode of the organic electroluminescence element includes Ag or an alloy containing Ag as a principal component.

5. The display device according to claim 4, wherein the electrode formed closest to a side of the display panel includes Ag or an alloy containing Ag as a principal component.

6. The display device according to claim 4, wherein the electrode includes Ag or an alloy containing Ag as a principal component is formed on an underlayer including compound containing nitrogen atom.

7. The display device according to claim 4, wherein, in the organic electroluminescence element in which the light-emitting units are laminated, an intermediate electrode formed between the laminated light-emitting units includes Ag or an alloy containing Ag as a principal component.

8. The display device according to claim 2, wherein gradation data of image signal of the white light or yellow light is α×M (provided that α is 0 or more and 1 or less), when the smallest image signal among image signals of red light, green light and blue light is gradated to M gradation.
